(19) United States
(12) Patent Application Publication
(10) Pub. No.: US 2023/0198472 A1
(43) Pub. Date: Jun. 22, 2023

(54) Amplifier Circuit

(71) Applicant: Nippon Telegraph and Telephone Corporation, Tokyo (JP)

(72) Inventors: Hiroshi Hamada, Tokyo (JP); Hideyuki Nosaka, Tokyo (JP)

(21) Appl. No.: 17/926,428

(22) PCT Filed: Nov. 16, 2020
(86) PCT No.: PCT/JP2020/042566

§ 371 Date: Nov. 18, 2022

(30) Foreign Application Priority Data
May 29, 2020 (WO) PCT/JP2020/021349
Aug. 3, 2020 (WO) PCT/JP2020/029664

(51) Int. Cl. H03F 1/14; H03F 3/19

(52) U.S. Cl. CPC H03F 1/14; H03F 3/19

(57) ABSTRACT

An amplifier circuit includes source-grounded amplifiers and a neutralization circuit that is connected between drain terminals and gate terminals of the source-grounded amplifiers and neutralizes a feedback capacitance of the source-grounded amplifiers, and the neutralization circuit includes transmission lines and a capacitor connected in series.

### CROSS-REFERENCE TO RELATED APPLICATIONS

This application is a national phase entry of PCT Application No. PCT/JP2020/042566, filed on Nov. 16, 2020, which claims priority of PCT/JP2020/029664, filed on Aug. 3, 2020 and PCT/JP2020/021349, filed on May 29, 2020, which applications are hereby incorporated herein by reference.

### TECHNICAL FIELD

The present disclosure relates to a circuit technology for handling high frequency electrical signals.

### BACKGROUND

A method using a neutralization circuit is known as a scheme of constructing an amplifier circuit having a large gain in the vicinity of a maximum oscillation frequency of a transistor (see, for example, NPL 1).

A neutralization circuit is a circuit having a function of canceling (neutralizing) a feedback capacitance between an input and an output, which is a factor that reduces a gain of a transistor, through resonance with an inductance provided outside the transistor. This makes it possible to increase a gain of a transistor amplifier at a resonance frequency.

FIG. 16 illustrates a configuration of an FET source-grounded amplifier using a neutralization circuit using a transmission line. A feedback capacitance C_{F} is a drain-gate capacitance (C_{dg}) in the case of a source-grounded amplifier using an FET and is a collector-base capacitance (C_{eb}) in the case of an emitter-grounded amplifier using a bipolar transistor.

In FIG. 16, a resonance frequency (hereinafter referred to as a neutralization frequency f_{N}) determined by the feedback capacitance C_{F} and an inductance L_{N} of the neutralization circuit is given by Equation (1) below.

$$\begin{matrix}Equation 1 & \\ {f}_{N} = \frac{1}{2 π \sqrt{{L}_{N} {C}_{F}}} & ( 1 )\end{matrix}$$

Considering Equation (1) and a typical feedback capacitance value C_{F}=C_{dg}=10 fF of an InP-based high electron mobility transistor (InP-HEMT with a gate width of 20 μm) used in an ultra-high frequency band, it is possible to draw a graph showing a relationship between the neutralization frequency and the inductance L_{N} of the neutralization circuit for achieving the neutralization frequency, as illustrated in FIG. 17.

From FIG. 17, it can be seen that an inductance value for the neutralization frequency decreases when the neutralization frequency increases. Thus, to perform neutralization in an ultra-high frequency band of 500 GHz, it is preferable to set the inductance value L_{N} to a very small value of 10 pH.

FIG. 18 illustrates a result of calculating a relationship between a transmission line length (L_TL) and the inductance value. In FIG. 18, as a transmission line, a coplanar line (CPW) having a characteristic impedance of 50Ω, which is a typical line used in an ultra-high frequency circuit, is used. According to FIG. 18, it can be seen that the transmission line length (L_TL) should be set to a very short value of 20 μm or less in order to achieve an inductance of 10 pH.

### CITATION LIST

### Non Patent Literature

[NPL 1] D. Parveg, et al., “Demonstration of a 0.325-THz CMOS Amplifier,” 2016 Global Symposium on Millimeter Waves (GSMM) & ESA Workshop on Millimetre-Wave Technology and Applications, June 2016.

### SUMMARY

### Technical Problem

It will be examined whether such a neutralization circuit having a short transmission line length can be arranged in an actual circuit layout. FIG. 19 illustrates an example of a physical layout of a source-grounded amplifier using the FET of FIG. 16.

As described above, because the gate width of the FET having a C_{F} of 10 fF is 20 μm, a device length in FIG. 16 is 20 μm. As illustrated in FIG. 19, because the neutralization circuit 400 needs to be arranged to bypass the device, the transmission line length of the neutralization circuit 400 is always 20 μm or more.

Considering wiring manufacturing rules and the like, the transmission line length of the neutralization circuit 400 is about 40 μm or more at the shortest. According to FIG. 18, the inductance in this case is 10 pH or more. Thus, considering the actual circuit layout, it is impossible to achieve an inductance value of 10 pH that neutralizes an FET having a feedback capacitance value of 10 fF at 500 GHz in a neutralization circuit using a transmission line. Further, according to FIG. 17, when the frequency is higher than 500 GHz, the inductance value for neutralization becomes even smaller, and thus this problem becomes more remarkable.

Thus, in an ultra-high frequency band such as a 500 GHz band, a length of the neutralization circuit for neutralizing a feedback capacitance of the FET is close to a physical length of the transistor or shorter than the physical length of the transistor. Due to this, there is a problem that a layout of the neutralization circuit becomes impossible and an amplifier circuit using the neutralization circuit cannot be implemented.

The present disclosure has been made to solve the above problem, and an object of the present disclosure is to implement an amplifier circuit using a neutralization circuit in an ultra-high frequency band such as a 500 GHz band.

### Means for Solving the Problem

In order to solve the above problem, the amplifier circuit of the present disclosure includes a source-grounded amplifier, and a neutralization circuit that is connected between a drain terminal and a gate terminal of the source-grounded amplifier and neutralizes a feedback capacitance of the source-grounded amplifier, in which the neutralization circuit includes a transmission line and a capacitor that is connected in series.

In order to solve the above problem, an amplifier circuit of the present disclosure includes a source-grounded amplifier, and a neutralization circuit that is connected between a drain terminal and a gate terminal of the source-grounded amplifier and neutralizes a feedback capacitance of the source-grounded amplifier, in which the neutralization circuit includes a transmission line and a coupling line that is connected in series.

In order to solve the above problem, an amplifier circuit of the present disclosure includes an emitter-grounded amplifier, and a neutralization circuit that is connected between a base terminal and a collector terminal of the emitter-grounded amplifier and neutralizes a feedback capacitance of the emitter-grounded amplifier, in which the neutralization circuit includes a transmission line and a capacitor that is connected in series.

In order to solve the above problem, an amplifier circuit of the present disclosure includes an emitter-grounded amplifier, and a neutralization circuit that is connected between a base terminal and a collector terminal of the emitter-grounded amplifier and neutralizes a feedback capacitance of the emitter-grounded amplifier, in which the neutralization circuit includes a transmission line and a coupling line that is connected in series.

### Effects of Embodiments of the Invention

According to the present disclosure, it is possible to implement an amplifier circuit using a neutralization circuit in an ultra-high frequency band such as a 500 GHz band.

### BRIEF DESCRIPTION OF THE DRAWINGS

FIG. 1 illustrates a configuration example of an amplifier circuit according to a first embodiment of the present disclosure.

FIG. 2 illustrates a result of calculating an equivalent inductance of a neutralization circuit according to the first embodiment of the present disclosure.

FIG. 3 illustrates a configuration example of an amplifier circuit in which a plurality of stages of amplifier circuits of the related art are connected.

FIG. 4 illustrates a configuration example of an amplifier circuit in which a plurality of stages of the amplifier circuits according to the first embodiment of the present disclosure are connected.

FIG. 5 illustrates a result of calculating a small-signal gain of an amplifier according to the first embodiment of the present disclosure.

FIG. 6 illustrates a calculation result for explaining effects of a resistor of a bias circuit for a drain.

FIG. 7 illustrates a configuration example of an amplifier circuit according to a second embodiment of the present disclosure.

FIG. 8 illustrates a result of calculating an equivalent inductance of a neutralization circuit according to the second embodiment of the present disclosure.

FIG. 9 illustrates a result of calculating a small-signal gain of the amplifier circuit according to the second embodiment of the present disclosure.

FIG. 10 illustrates a configuration example of an amplifier circuit according to a third embodiment of the present disclosure.

FIG. 11 illustrates a configuration example of an amplifier circuit according to a fourth embodiment of the present disclosure.

FIG. 12 illustrates a configuration example of an amplifier circuit according to a fifth embodiment of the present disclosure.

FIG. 13 illustrates a result of calculating a maximum gain of the amplifier circuit according to the fifth embodiment of the present disclosure.

FIG. 14 illustrates a configuration example of an amplifier circuit in which a plurality of stages of the amplifier circuits according to the fifth embodiment of the present disclosure are connected.

FIG. 15 illustrates a gain simulation result of the amplifier circuit according to the fifth embodiment of the present disclosure.

FIG. 16 illustrates a configuration example of an amplifier of the related art.

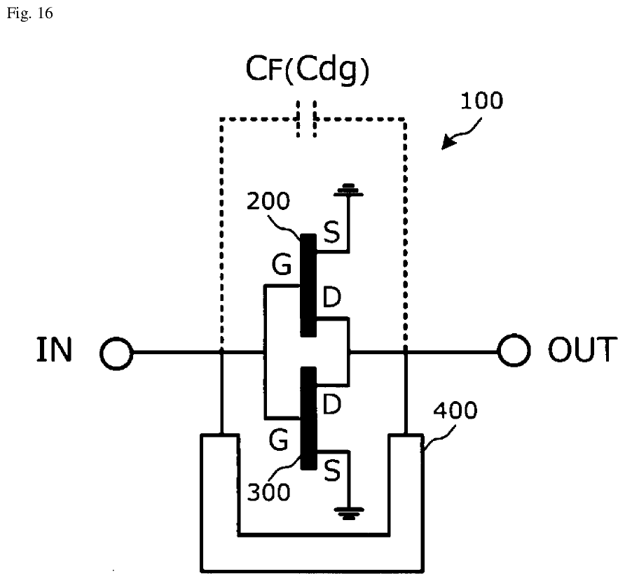

FIG. 17 is a diagram illustrating a relationship between a neutralization frequency and an inductance value of the neutralization circuit.

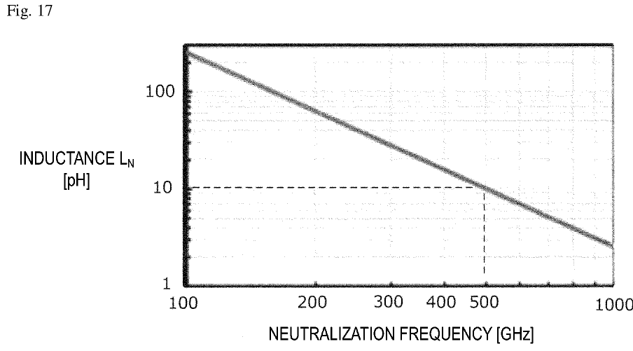

FIG. 18 is a diagram illustrating a relationship between a transmission line length and the inductance value.

FIG. 19 is a diagram illustrating a circuit layout of a source-grounded amplifier using an FET.

### DETAILED DESCRIPTION OF ILLUSTRATIVE EMBODIMENTS

Hereinafter, embodiments of the present disclosure will be described in detail with reference to the drawings. The present disclosure is not limited to the following embodiments.

### First Embodiment

In the present disclosure, to solve the above problem, a small inductance value capable of neutralizing a feedback capacitance of a transistor is achieved in a neutralization circuit having a physical length sufficiently longer than the physical length of the transistor. The neutralization circuit of the present disclosure includes transmission lines and a capacitor connected in series.

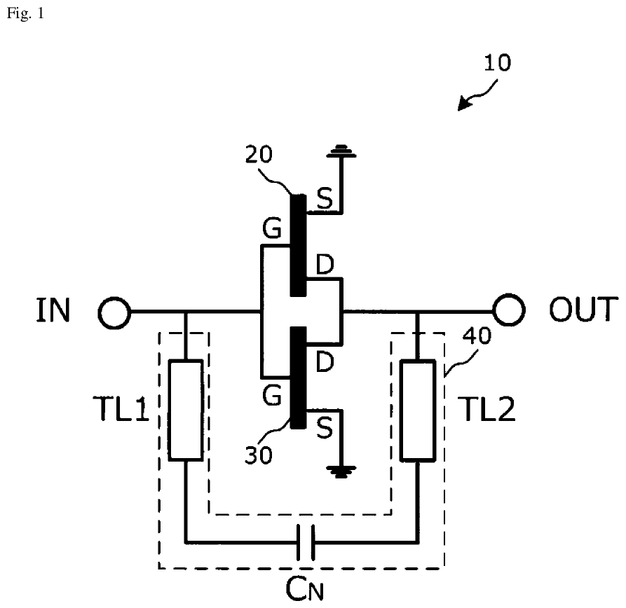

FIG. 1 illustrates a configuration example of an amplifier circuit according to a first embodiment of the present disclosure. An amplifier circuit 10 of the present embodiment includes FET source-grounded amplifiers (20 and 30), and a neutralization circuit 40 that neutralizes a feedback capacitance of an FET between drain terminals and gate terminals of the FET source-grounded amplifiers (20 and 30).

In the configuration example of FIG. 1, two transmission lines and a capacitor connected between the two transmission lines are included, but the number of transmission lines and a position of the capacitor are not limited to the configuration of FIG. 1. For example, a capacitor connected in series with one transmission line may be included. The number of transmission lines and the position of the capacitor can be appropriately designed according to a circuit layout to be implemented.

Further, the amplifier may be configured by a bipolar transistor. The amplifier circuit in this case includes an emitter-grounded amplifier and a neutralization circuit including transmission lines and a capacitor connected in series, and the neutralization circuit is configured to be connected between a base terminal and a collector terminal of the emitter-grounded amplifier.

An ordinary neutralization circuit as illustrated in NPL 1 includes only a transmission line, whereas the neutralization circuit of the present embodiment includes two transmission lines (TL 1 and TL 2) and a capacitor C_{N} connected in series with the transmission lines (TL 1 and TL 2). In this configuration, an equivalent inductance L_{eq} of the two transmission lines (TL 1 and TL 2) and the capacitor C_{N} acts to neutralize a feedback capacitance of the FET source-grounded amplifiers (20 and 30).

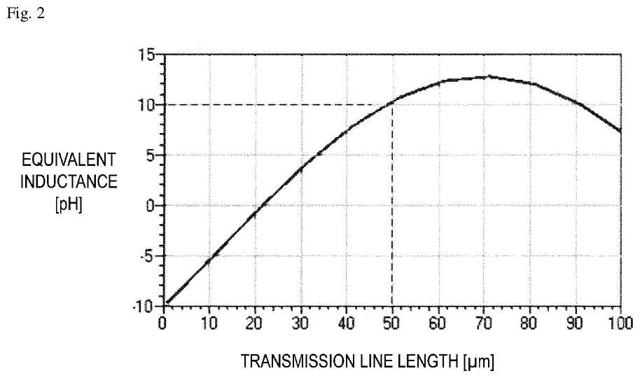

FIG. 2 illustrates a result of calculating the equivalent inductance L_{eq} of the neutralization circuit at 500 GHz when specific values are applied to the neutralization circuit 40 of FIG. 1. Here, a transmission line length L_TL of the neutralization circuit 40 consists of a length of the transmission lines (TL 1 and TL 2) and a length of the capacitor C_{N}, and the length of each of the transmission lines (TL 1 and TL 2) was half a length excluding the length of the capacitor C_{N}. The capacitor C_{N} was set to 10 fF, which is a value that can be achieved in an integrated circuit process.

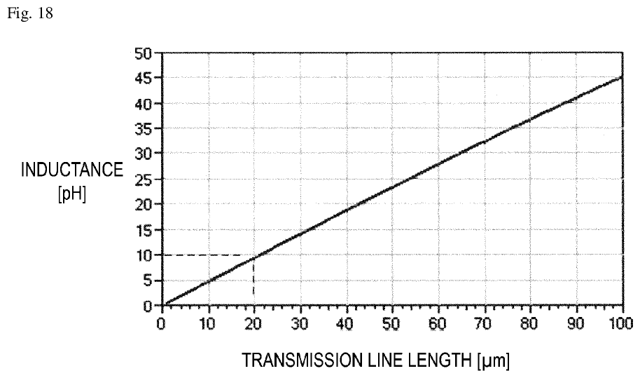

According to FIG. 2, it can be seen that a value of the transmission line length L_TL of the neutralization circuit 40 when the equivalent inductance L_{eq} is 10 pH is 50 μm, which is larger than 20 μm in the case of FIG. 18. When the length is 50 μm, because this length is sufficiently larger than the device length of 20 μm of the FET source-grounded amplifiers (20 and 30), a layout of the neutralization circuit 40 is possible.

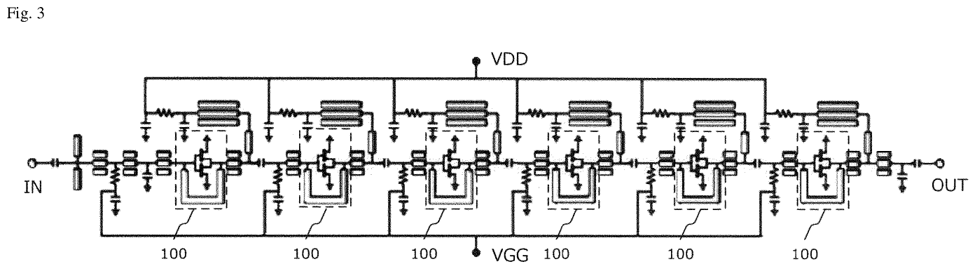

FIG. 3 illustrates an amplifier circuit in which a plurality of stages of an amplifier circuit 100 using a neutralization circuit 400 of the related art are connected. An input and output matching circuit of the amplifier circuit is designed for matching at about 500 GHz. Further, an HEMT having a gate width of 20 μm is used as the FET. 50 μm, which is a value allowing a physical layout, is adopted as a length of the neutralization circuit 400.

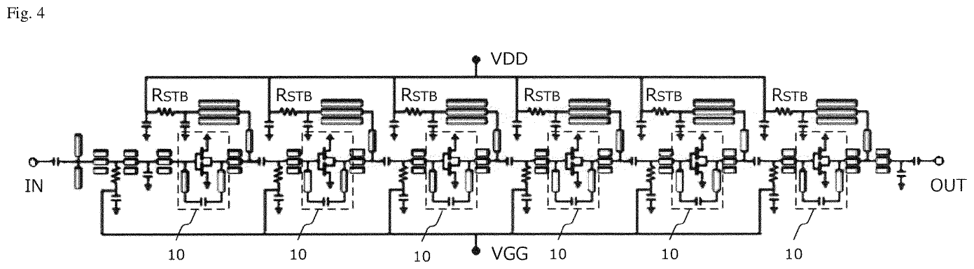

FIG. 4 illustrates an amplifier circuit in which a plurality of stages of amplifier circuits 10 using a neutralization circuit 40 of the present embodiment are connected. Parameters other than those of the neutralization circuit 40 are exactly the same as those in FIG. 3. A value of the capacitor C_{N} of the neutralization circuit 40 was set to 10 fF. According to FIG. 18, an inductance value of the neutralization circuit 400 in FIG. 3 is about 23 pH. On the other hand, according to FIG. 2, the equivalent inductance value L_{eq} of the neutralization circuit 40 in FIG. 4 is about 10 pH.

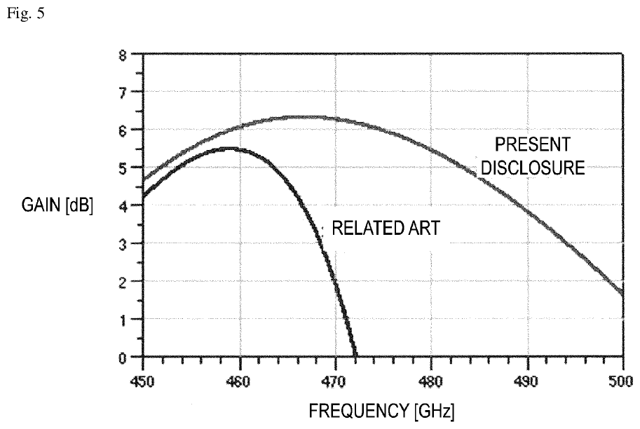

A result of calculating a small-signal gain obtained in the circuits of FIGS. 3 and 4 is illustrated in FIG. 5. In the amplifier circuit 100 of the related art, because an inductance value of the neutralization circuit 400 cannot be reduced, the gain becomes 0 dB or less at a frequency of 472 GHz or higher.

On the other hand, in the present embodiment, it can be seen that a large gain can also be obtained at a frequency of 472 GHz or higher by using the neutralization circuit 40 including the transmission lines and the capacitor connected in series. This is because, with the present embodiment, a small inductance value required for implementation of a neutralization circuit in an ultra-high frequency band can be achieved. According to the present embodiment, it is possible to lay out a neutralization circuit having an inductance value for canceling a feedback capacitance of the transistor also in an ultra-high frequency band.

According to the present embodiment, other remarkable effects can be obtained. That is, bias voltages for a gate and a drain of an FET (bias voltages for a base and a collector in the case of a bipolar transistor) can be set individually. In the case of a CMOS amplifier as in NPL 1, a large gain can often be obtained also when a bias voltage for a gate and a drain is common, but in the case of a compound semiconductor such as an HEMT, bias voltages for a gate and a drain are normally set to different voltage values to obtain a large gain.

In particular, in the case of a normally-on transistor such as an InP-HEMT, a positive voltage is applied to a drain and a negative voltage is applied to a gate normally, and thus a gain cannot be obtained with the configuration of FIG. 3 in the related art. In FIG. 5, because a bias application condition is not reflected due to a design using a small-signal model at an optimal gain voltage (VDD=1.2 V and VGG=−0.2 V) of an InP-HEMT, a gain is also obtained in the circuit of FIG. 3, but in reality, in the circuit of FIG. 3, because the drain and the gate can be biased only to the same potential, a small-signal gain is further smaller than that illustrated in FIG. 5.

In the present embodiment, because the drain and the gate are DC-isolated by the series capacitor included in the neutralization circuit, it is possible to individually bias the drain and the gate and to obtain good amplification characteristics also in a normally-on transistor such as an InP-HEMT.

Here, in a circuit diagram (FIG. 4) according to the present embodiment, a resistor connected in series with a transmission line is arranged in a bias circuit for applying a bias voltage for a drain of each amplifier. Effects of a series resistor included in the bias circuit for a drain will be described. This series resistor is intended to prevent an out-of-band gain and oscillation of the amplifier circuit.

In the amplifier circuit using the neutralization circuit as in the present disclosure, because the neutralization circuit has no action of canceling the feedback capacitance of the transistor in frequencies other than the neutralization frequency (a frequency satisfying Equation (1)), an operation of the amplifier circuit may be unstable in a frequency band other than the neutralization frequency. In such a case, an undesired gain (out-of-band gain) or oscillation typically occurs at a frequency other than the neutralization frequency. It is preferable to eliminate the out-of-band gain and the oscillation because the out-of-band gain and the oscillation impair the quality of the amplifier circuit.

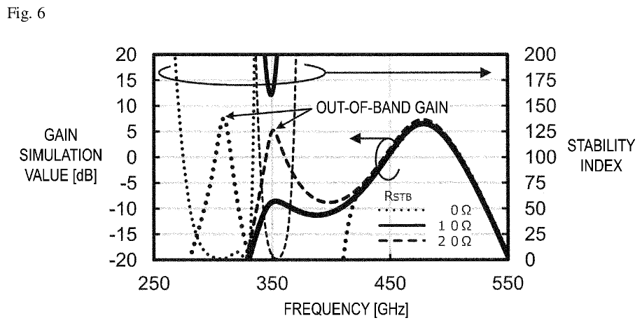

Thus, it is possible to cause a loss of a signal outside the band and to eliminate the out-of-band gain and the oscillation by disposing the series resistor having an appropriate resistance value on the transmission line of the bias circuit for a drain as illustrated in FIG. 4. In FIG. 4, a resistance value of this series resistor arranged in each stage is R_{STB}, and a result of calculating a gain and a stability index (1 or more indicates that it is stable without oscillation) of the amplifier circuit when R_{STB} is changed to 0, 10, and 20Ω is illustrated in FIG. 6.

In FIG. 6, when R_{STB} is 0Ω or 20Ω, a peak of the gain occurs outside the band, and the stability index at that frequency is also smaller than 1. On the other hand, it can be seen that, when R_{STB} is set to 10Ω, the out-of-band gain and the oscillation are eliminated, and the circuit is stabilized. As described above, because such instability characteristics of the circuit are likely to occur outside the band in the neutralization circuit, the insertion of the resistor in the bias circuit for a drain as used in FIG. 4 is very important. For a value of R_{STB}, a predetermined resistance value is appropriately set so that the out-of-band gain does not occur, the stability index becomes 1 or more, and the circuit is stabilized, according to a configuration and parameters of the amplifier circuit.

Further, it is possible to decrease a Q value of resonance of the neutralization circuit and to widen a band of the amplifier by disposing the series resistor in the neutralization circuit. This point will be described in detail in a fifth embodiment.

### Second Embodiment

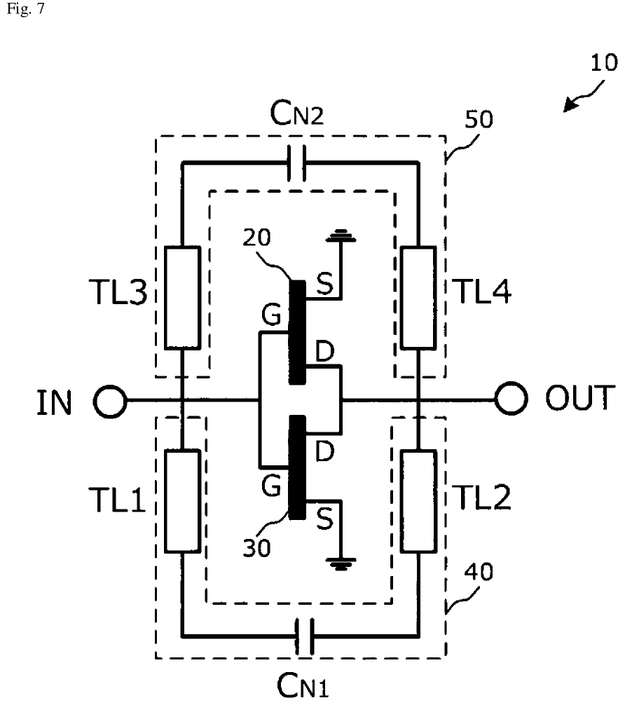

As a second embodiment of the present disclosure, a technology for increasing a frequency of the amplifier by further reducing the inductance of the neutralization circuit described in the first embodiment will be described. FIG. 7 is a configuration example of an amplifier circuit according to a second embodiment of the present disclosure. The neutralization circuit 40 of the first embodiment is arranged on both sides of the transistor. Two neutralization circuits (40 and 50) are arranged in parallel between drain terminals and gate terminals of FET source-grounded amplifiers (20 and 30).

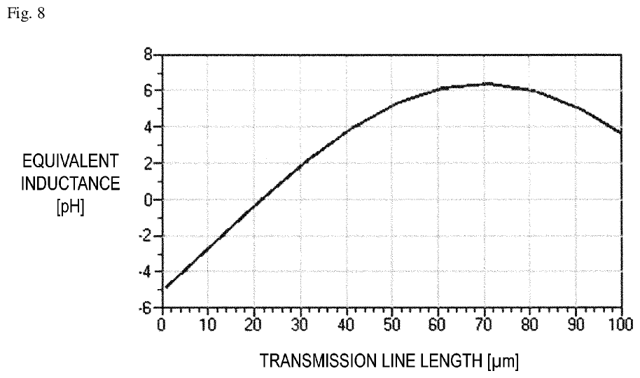

Such a form allows a total inductance Leq of the neutralization circuits (40 and 50) to be further half the inductance in the first embodiment. A result of calculating an equivalent inductance Leq in the neutralization circuit in FIG. 7 is illustrated in FIG. 8. According to FIG. 7, it can be seen that half the inductance value of the first embodiment is achieved.

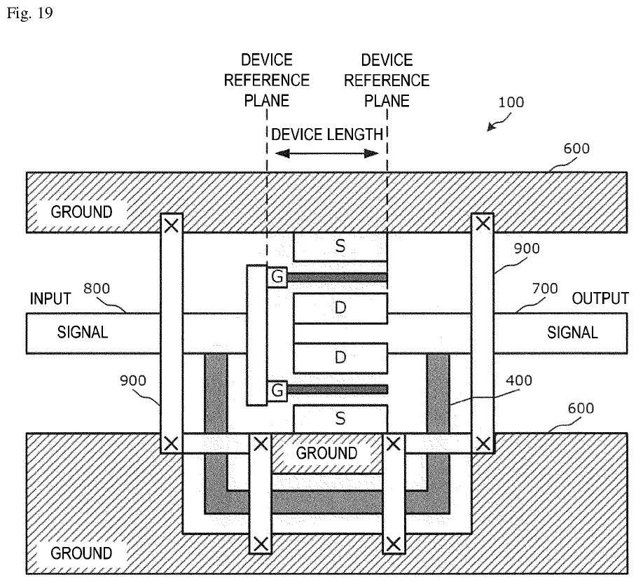

A configuration as illustrated in FIG. 7 can be achieved by a configuration in which neutralization circuits are arranged on both sides of a signal line in the circuit layout illustrated in FIG. 19. Further, in FIG. 7, the two neutralization circuits (40, 50) are arranged in parallel, but three or more neutralization circuits may be arranged.

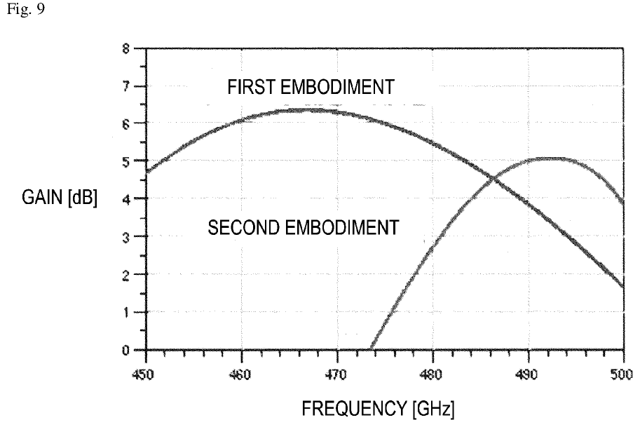

A result of calculating a small-signal gain of the amplifier circuit when the amplifier circuit 10 in FIG. 7 has been applied is illustrated in FIG. 9. In FIG. 8, parameters other than the neutralization circuit were the same as those in the case of FIG. 5. According to FIG. 9, it can be seen that a further smaller inductance value can be achieved by the neutralization circuit of the second embodiment, and an amplifier having a gain at a higher frequency can be implemented.

### Third Embodiment

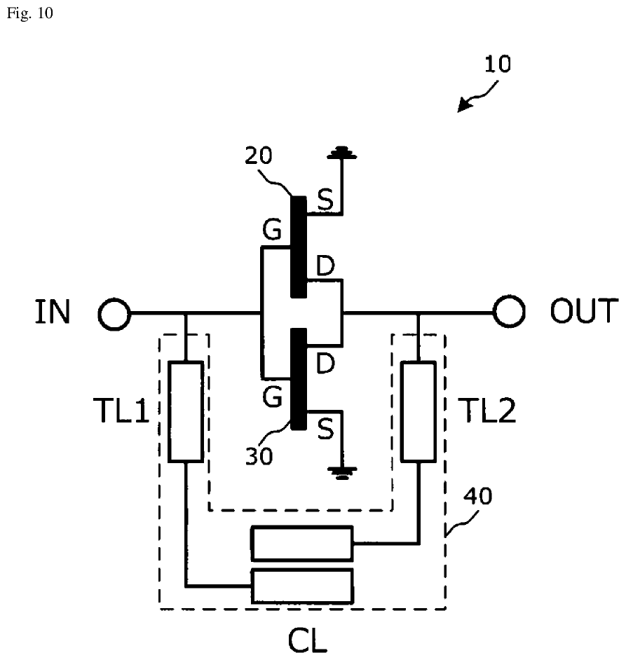

In the first and second embodiments, the inductance of the neutralization circuit is reduced, and the neutralization frequency is improved by using the capacitor in the neutralization circuit. The same effect can be obtained by using a coupling line CL instead of the capacitor, as illustrated in FIG. 10.

In this case, a line proximate to drains and a line proximate to gates forming a neutralization circuit 40 are separated but are AC-coupled due to the nature of the coupling line CL. In the case of a capacitance by a normal semiconductor process such as a metal-insulator-metal (MIM) capacitance, there is a lower limit to a capacitance value that can be achieved due to constraints of a process rule, but the coupling line CL has weaker coupling between the coupling lines than the MIM capacitance (a capacitance per unit length is small), so that a capacitance value smaller than the MIM capacitance can be achieved. Thus, this is an effective means for increasing a frequency of the neutralization circuit.

### Fourth Embodiment

In the first to third embodiments, the neutralization circuit is present independently of the bias circuit for applying the bias of the drain, as illustrated in FIG. 4. However, in a circuit layout, it may be difficult to dispose the two lines other than a main signal line (a line connecting transistor stages of a multi-stage amplifier circuit) around the transistor.

For example, in a power amplifier, a plurality of amplifier circuits are arranged in parallel to take out power. In this case, physical sizes of lines other than the two main signal lines become constraints, and it is conceivable that the number of parallel dispositions decreases.

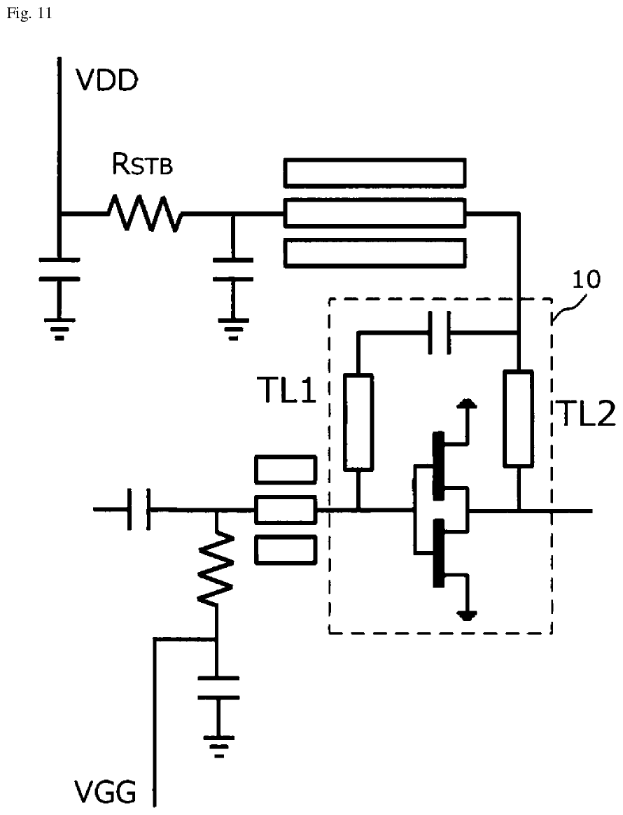

FIG. 11 illustrates a configuration example of an amplifier circuit according to a fourth embodiment of the present disclosure. In the fourth embodiment, a part of the transmission line of a bias circuit for applying a bias of a drain is used as a transmission line of the neutralization circuit, as illustrated in FIG. 11. The use of the transmission line of the bias circuit as the transmission line of the neutralization circuit makes it possible to combine lines other than the main signal line into one and to reduce a physical size of the amplifier circuit.

### Fifth Embodiment

In the first to fourth embodiments, the neutralization circuit 40 includes only reactive elements such as the transmission line or the capacitor. In such a configuration, because there is no power loss in the neutralization circuit 40, there is a characteristic in that a large gain can be obtained near an operating frequency of the neutralization circuit 40 (a frequency at which a parasitic capacitance of the transistor is canceled). Here, because a resonance phenomenon in the neutralization circuit is used, there is a characteristic in that an operating band thereof is determined by the Q value of the resonance, and an operating band of the amplifier circuit is relatively narrow. In the present embodiment, a form of the amplifier circuit 10 using the fact that a large gain can be taken out from a transistor amplifier in a wide band by decreasing the Q value of the resonance through causing some power consumption in the neutralization circuit 40 will be described.

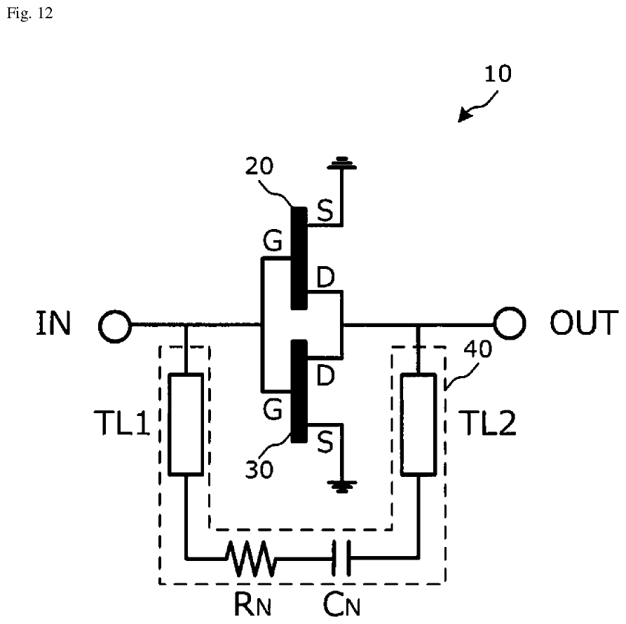

FIG. 12 illustrates a configuration example of the amplifier circuit 10 with the neutralization circuit 40 according to the present embodiment. A resistor R_{N} is loaded in series with the neutralization circuit 40 in FIG. 1. With this resistor R_{N}, it is possible to decrease the Q value of the resonance of the neutralization circuit 40 and, as a result, to take out a gain in a wide band from the transistor amplifier.

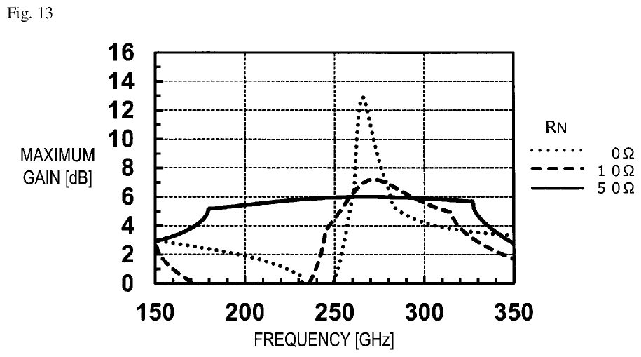

FIG. 13 illustrates a result of calculating frequency characteristics of a maximum gain that can be taken out from the transistor amplifier. The values of the transmission line and the capacitor of the neutralization circuit are set so that the parasitic capacitance of the transistor is canceled at 270 GHz. Specifically, both two transmission lines have a characteristic impedance of 50Ω, an electric length of 30°, and a capacitance of 20 fF.

It can be seen that, when a value of the series resistor R_{N} is 0Ω, that is, when the resistor is not loaded, a result indicated by a dotted line in FIG. 13 is obtained and a large gain of 13 dB can be taken out near 270 GHz, but a bandwidth itself of the gain is relatively narrow and a 3 dB bandwidth is only about 10 GHz. To widen this band, a resistance value of the resistor R_{N} is increased. When the resistance value of R_{N}=10Ω is applied, a result is as indicated by a broken line in FIG. 13. Although a maximum value of the gain is reduced to 7 dB, it is possible to extend the 3 dB bandwidth to 75 GHz. Further, it can be seen that, when the value of the resistor R_{N} is set to 50Ω, the gain is 6 dB and the 3 dB bandwidth can be extended to 200 GHz, as indicated by a solid line in FIG. 13.

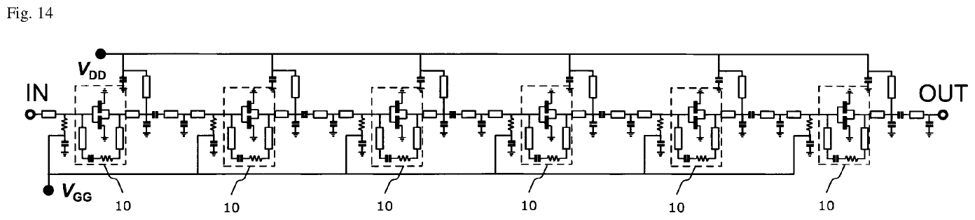

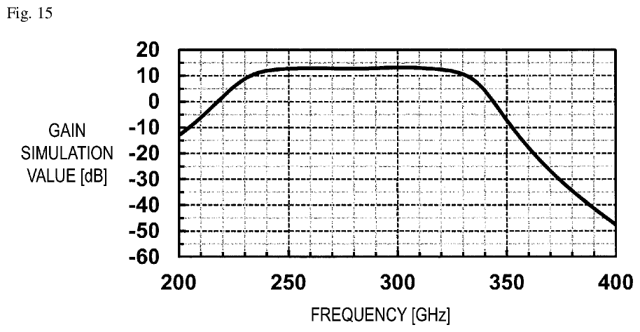

FIG. 14 illustrates a configuration example of an amplifier circuit in a 300 GHz band using six stages of amplifier circuits 10 with the neutralization circuits of FIG. 12. In this configuration example, a value of a series resistor inserted into the neutralization circuit 10 of each stage was set to 50Ω. A gain simulation result of the amplifier circuit in FIG. 14 is illustrated in FIG. 15. It can be seen that a very wide band and high gain amplifier with a maximum gain of 12.5 dB and a 3 dB bandwidth of 100 GHz can be implemented.

In the present embodiment, a bandwidth and a gain that are obtained are in a trade-off relationship, as illustrated in FIG. 13. Thus, when the amplifier circuit of the present embodiment is applied to an actual circuit, a gain and a band of each stage of the amplifier circuit to achieve a target gain and a target band of the circuit are defined, and the value of the resistor is first determined according to the defined values.

In the configuration example of FIG. 12, the neutralization circuit 40 includes two transmission lines and a capacitor C_{N} and the resistor R_{N} connected between the two transmission lines, but the number of transmission lines and positions of the capacitor and the resistor are not limited to the configuration in FIG. 12 and can be appropriately designed according to a circuit layout to be implemented, as in the first to fourth embodiments. Further, the coupling line CL may be used instead of the capacitor C_{N}, as illustrated in FIG. 10.

Further, in FIG. 12, the transistor amplifier is composed of the FET source-grounded amplifier, but the transistor amplifier may be composed of an emitter-grounded amplifier, as in the first to fourth embodiments.

### Expansion of Embodiment

Although the present disclosure has been described above with reference to the embodiments, the present disclosure is not limited to the above embodiments. Various modifications that can be understood by those skilled in the art within the scope of the present disclosure can be made to the configuration of the present disclosure.

### REFERENCE SIGNS LIST

10 Amplifier circuit
20, 30 Source-grounded amplifier
40, 50 Neutralization circuit.

1-12. (canceled)

13. An amplifier circuit comprising:
an amplifier including a transistor, wherein a first terminal of the transistor is grounded; and
at least one neutralization circuit connected between a second terminal and a third terminal the transistor, wherein the at least one neutralization circuit is configured to neutralize a feedback capacitance of the amplifier, and wherein the at least one neutralization circuit includes a first transmission line and a capacitor connected in series.

14. The amplifier circuit according to claim 13, wherein:
the amplifier is a source-grounded amplifier composed of an InP-HEMT, and
the second terminal and the third terminal are biased at different potentials.

15. The amplifier circuit according to claim 13, wherein the at least one neutralization circuit further includes a second transmission line, and wherein the capacitor is connected between the first transmission line and the second transmission line.

16. The amplifier circuit according to claim 13, wherein the at least one neutralization circuit further includes a resistor connected in series with the first transmission line and the capacitor.

17. The amplifier circuit according to claim 13, further comprising:
a bias circuit configured for bias application, wherein a series resistor having a predetermined resistance value is arranged on a transmission line of the bias circuit.

18. The amplifier circuit according to claim 13, further comprising
a bias circuit configured for bias application, wherein a transmission line of the bias circuit is also used as the first transmission line of the at least one neutralization circuit.

19. The amplifier circuit according to claim 13, wherein the at least one neutralization circuit includes two or more neutralization circuits arranged in parallel.

20. An amplifier circuit comprising:
an amplifier including a transistor, wherein a first terminal of the transistor is grounded; and
at least one neutralization circuit connected between a second terminal and a third terminal of the transistor, wherein the at least one neutralization circuit is configured to neutralize a feedback capacitance of the amplifier, and wherein the at least one neutralization circuit includes a first transmission line and a coupling line connected in series.

21. The amplifier circuit according to claim 20, wherein:
the amplifier is a source-grounded amplifier composed of an InP-HEMT, and
the second terminal and the third terminal are biased at different potentials.

22. The amplifier circuit according to claim 20, wherein the at least one neutralization circuit further includes a second transmission line, and wherein the coupling line is connected between the first transmission line and the second transmission line.

23. The amplifier circuit according to claim 20, wherein the at least one neutralization circuit further includes a resistor connected in series with the first transmission line and the coupling line.

24. The amplifier circuit according to claim 20, further comprising:
a bias circuit configured for bias application, wherein a series resistor having a predetermined resistance value is arranged on a transmission line of the bias circuit.

25. The amplifier circuit according to claim 20, further comprising
a bias circuit configured for bias application, wherein a transmission line of the bias circuit is also used as the first transmission line of the at least one neutralization circuit.

26. The amplifier circuit according to claim 20, wherein the at least one neutralization circuit includes two or more neutralization circuits arranged in parallel.
